(19) United States
(12) Patent Application Publication
(10) Pub. No.: US 2012/0168774 A1
(43) Pub. Date: Jul. 5, 2012

(54) SILICON CARBIDE SUBSTRATE AND METHOD FOR MANUFACTURING SAME

(75) Inventors: Takeyoshi Masuda, Osaka-shi (JP); Satomi Itoh, Osaka-shi (JP); Shin Harada, Osaka-shi (JP); Makoto Sasaki, Itami-shi (JP)

(73) Assignee: Sumitomo Electric Industries, Ltd., Osaka-shi, Osaka (JP)

(21) Appl. No.: 13/395,768

(22) PCT Filed: May 19, 2011
(86) PCT No.: PCT/JP2011/061485

§ 371 Date: Mar. 13, 2012

(30) Foreign Application Priority Data
May 28, 2010 (JP) 2010-122704

(51) Int. Cl. H01L 29/24; H01L 21/20

(52) U.S. Cl. 257/77; 438/500; 257/E21.09; 257/E29.104

(57) ABSTRACT

A silicon carbide substrate and a method for manufacturing the silicon carbide substrate are obtained, each of which achieves reduced manufacturing cost of semiconductor devices using the silicon carbide substrate. A method for manufacturing a SiC-combined substrate includes the steps of: preparing a plurality of single-crystal bodies each made of silicon carbide (SiC); forming a collected body; connecting the single-crystal bodies to each other; and slicing the collected body. In the step, the plurality of SiC single-crystal ingots are arranged with a silicon (Si) containing Si layer interposed therebetween, so as to form the collected body including the single-crystal bodies. In the step, adjacent SiC single-crystal ingots are connected to each other via at least a portion of the Si layer, the portion being formed into silicon carbide by heating the collected body. In step, the collected body in which the SiC single-crystal ingots are connected to each other is sliced.

### TECHNICAL FIELD

The present invention relates to a silicon carbide substrate and a method for manufacturing the silicon carbide substrate, more particularly, to a silicon carbide substrate having a plurality of single-crystal regions connected to each other via a connecting layer, as well as a method for manufacturing the silicon carbide substrate.

### BACKGROUND ART

In recent years, in order to achieve high breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

Under such circumstances, various studies have been conducted on methods for manufacturing silicon carbide crystals and silicon carbide substrates used for manufacturing of semiconductor devices, and various ideas have been proposed (for example, see M. Nakabayashi, et al., “Growth of Crack-free 100 mm-diameter 4H—SiC Crystals with Low Micropipe Densities”, Mater. Sci. Forum, vols. 600-603, 2009, p. 3-6 (Non-Patent Literature 1)).

### CITATION LIST

### Non Patent Literature

NPL 1: M. Nakabayashi, et al., “Growth of Crack-free 100 mm-diameter 4H—SiC Crystals with Low Micropipe Densities”, Mater. Sci. Forum, vols. 600-603, 2009, p. 3-6.

### SUMMARY OF INVENTION

### Technical Problem

However, silicon carbide does not have a liquid phase at an atmospheric pressure. In addition, crystal growth temperature thereof is 2000° C. or greater, which is very high. This makes it difficult to control and stabilize growth conditions. Accordingly, it is difficult for a silicon carbide single-crystal to have a large diameter while maintaining its quality to be high. Hence, it is not easy to obtain a high-quality silicon carbide substrate having a large diameter. This difficulty in fabricating such a silicon carbide substrate having a large diameter results in not only increased manufacturing cost of the silicon carbide substrate but also fewer semiconductor devices produced for one batch using the silicon carbide substrate. Accordingly, manufacturing cost of the semiconductor devices is increased, disadvantageously. It is considered that the manufacturing cost of the semiconductor devices can be reduced by effectively utilizing a silicon carbide single-crystal, which is high in manufacturing cost, as a substrate.

In view of this, an object of the present invention is to provide a silicon carbide substrate and a method for manufacturing the silicon carbide substrate, each of which achieves reduced cost of manufacturing a semiconductor device using the silicon carbide substrate.

### Solution To Problem

A method for manufacturing a silicon carbide substrate in the present invention includes the steps of: preparing a plurality of single-crystal bodies each made of silicon carbide (SiC); forming a collected body; connecting the single-crystal bodies to each other; and slicing the collected body. In the step of forming the collected body, the plurality of single-crystal bodies are arranged with a silicon (Si) containing connecting layer interposed therebetween to form the collected body including the single-crystal bodies. In the step of connecting the single-crystal bodies to each other, adjacent single-crystal bodies are connected to each other by the connecting layer via at least a portion of the connecting layer, the at least portion being formed into silicon carbide by heating the collected body. In the step of slicing the collected body, the collected body in which the single-crystal bodies are connected to each other is sliced.

Thus, the plurality of SiC single-crystal bodies are connected to each other by the connecting layer formed into silicon carbide, so as to form a large ingot of silicon carbide. Then, this ingot is sliced. In this way, there can be efficiently obtained a plurality of silicon carbide substrates each having a size larger than that of an ingot obtained by slicing one single-crystal body. When the silicon carbide substrate thus having a large size is employed to manufacture semiconductor devices, a larger number of semiconductor devices (chips) can be formed in one silicon carbide substrate, as compared with the number in the conventional one. As a result, the manufacturing cost of the semiconductor devices can be reduced.

Further, because the large ingot formed as above is sliced to obtain the silicon carbide substrate of the present invention, a plurality of silicon carbide substrates can be manufactured at one time as compared with a case of forming silicon carbide substrates one by one by connecting single-crystal bodies each having a relatively thin thickness to each other. Accordingly, the manufacturing cost of the silicon carbide substrates can be reduced as compared with the case of forming silicon carbide substrates one by one by connecting single-crystal bodies each having a thin thickness.

A silicon carbide substrate according to the present invention includes: a plurality of single-crystal regions each made of silicon carbide; and a connection layer. The connection layer is made of silicon carbide, is located between the plurality of single-crystal regions, and connects the single-crystal regions to each other. Each of the single-crystal regions is formed to extend from a first main surface of the silicon carbide substrate to a second main surface thereof opposite to the first main surface. The single-crystal regions have substantially the same crystallinity in a direction of thickness from the first main surface to the second main surface. The plurality of single-crystal regions are different from each other in terms of crystal orientation in the first main surface. The connection layer has crystallinity inferior to that of each of the single-crystal regions.

With the configuration described above, the plurality of single-crystal regions are connected to each other by the connecting layer. Accordingly, there can be realized a silicon carbide substrate having a main surface having a larger area than that of a silicon carbide substrate constituted by one single-crystal region. Accordingly, a larger number of semiconductor devices can be obtained from one silicon carbide substrate during formation of semiconductor devices. This leads to reduced manufacturing cost of the semiconductor devices.

Further, the single-crystal regions have substantially the same crystallinity in the direction of thickness from the first main surface to the second main surface. Hence, when forming a vertical type device, a property in the thickness direction of the silicon carbide substrate does not cause a problem.

### Advantageous Effects of Invention

According to the present invention, there can be provided a silicon carbide substrate and a method for manufacturing the silicon carbide substrate, by each of which manufacturing cost of semiconductor devices can be reduced.

### BRIEF DESCRIPTION OF DRAWINGS

FIG. 1 is a flowchart showing a method for manufacturing a silicon carbide substrate according to the present invention.

FIG. 2 is a schematic view for illustrating the method for manufacturing the silicon carbide substrate shown in FIG. 1.

FIG. 3 is a schematic cross sectional view taken along a line in FIG. 2.

FIG. 4 is a schematic view for illustrating the method for manufacturing the silicon carbide substrate shown in FIG. 1.

FIG. 5 is a schematic view for illustrating the method for manufacturing the silicon carbide substrate shown in FIG. 1.

FIG. 6 is a schematic view for illustrating the method for manufacturing the silicon carbide substrate shown in FIG. 1.

FIG. 7 is a schematic view for illustrating the method for manufacturing the silicon carbide substrate shown in FIG. 1.

FIG. 8 is a schematic view for illustrating the method for manufacturing the silicon carbide substrate shown in FIG. 1.

FIG. 9 is a schematic planar view for illustrating another exemplary arrangement of the SiC single-crystal ingots in a step (S20) shown in FIG. 1.

FIG. 10 is a schematic planar view for illustrating still another exemplary arrangement of the SiC single-crystal ingots in step (S20) shown in FIG. 1.

FIG. 11 is a schematic cross sectional view showing a variation of the process in step (S20) of FIG. 1.

FIG. 12 is a schematic cross sectional view showing another variation of the process in step (S20) in FIG. 1.

FIG. 13 is a schematic cross sectional view showing still another variation of the process in step (S20) in FIG. 1.

FIG. 14 is a schematic cross sectional view showing yet another variation of the process in step (S20) in FIG. 1.

FIG. 15 is a schematic cross sectional view showing still another variation of the process in step (S20) in FIG. 1.

### DESCRIPTION OF EMBODIMENTS

The following describes embodiments of the present invention with reference to figures. It should be noted that in the below-mentioned figures, the same or corresponding portions are given the same reference characters and are not described repeatedly.

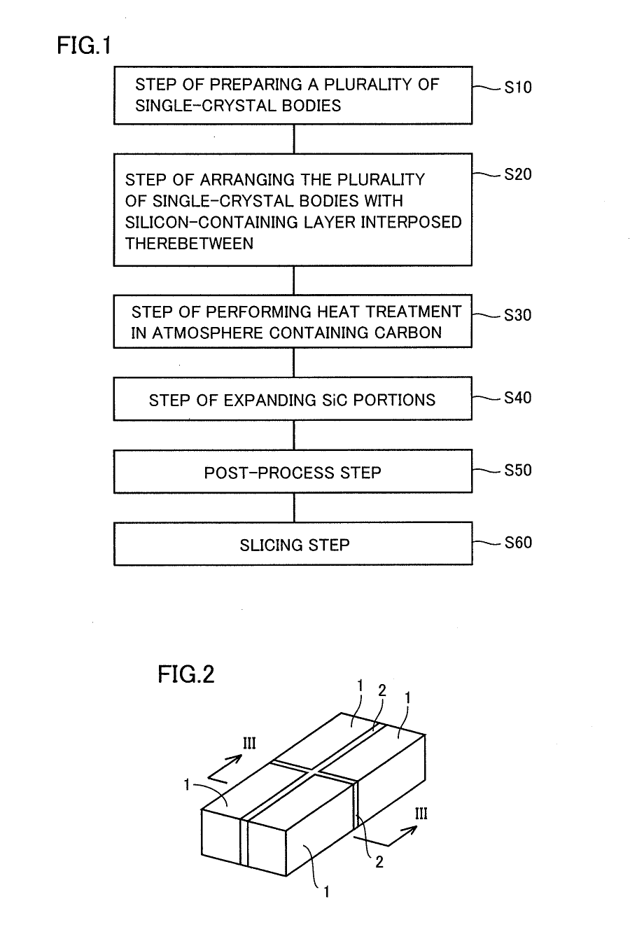

Referring to FIG. 1 to FIG. 8, the following describes a method for manufacturing a silicon carbide substrate according to the present invention.

As shown in FIG. 1, a step (S10) is first performed by preparing a plurality of single-crystal bodies. Specifically, as shown in FIG. 2, a plurality of silicon carbide (SiC) single-crystal ingots 1 are prepared.

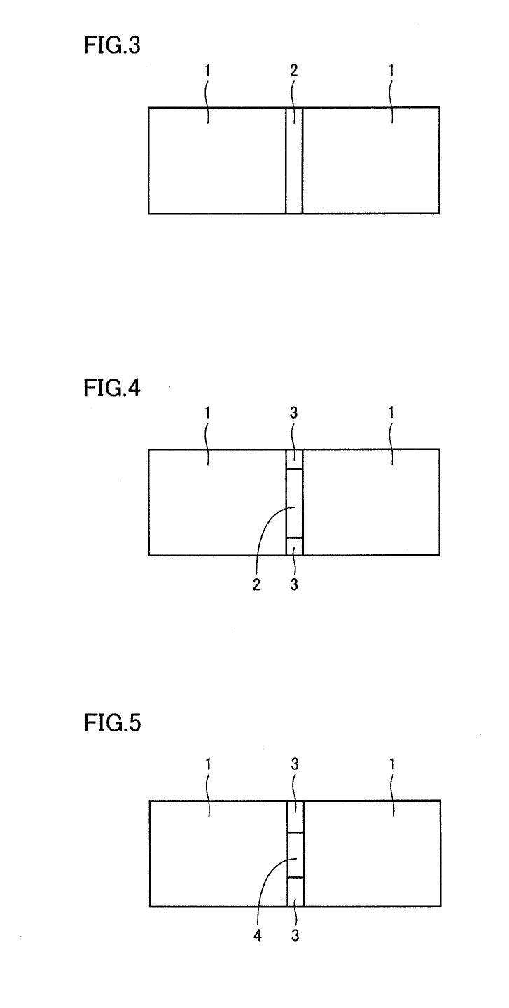

Next, a step (S20) is performed by arranging the plurality of single-crystal bodies with a silicon-containing layer interposed therebetween. Specifically, as shown in FIG. 2, the plurality of SiC single-crystal ingots 1 are disposed such that their opposing end surfaces face each other with a Si layer 2 interposed therebetween. Here, FIG. 2 is a schematic perspective view showing a collected body configured by arranging SiC single-crystal ingots 1 face to face with each other with Si layer 2 interposed therebetween. As understood from FIG. 2 and FIG. 3, in this step (S20), SiC single-crystal ingots 1 are disposed such that their opposing end surfaces are in contact with Si layer 2. As Si layer 2, any type of layer can be used so far as it is a layer containing Si as its main component. For example, as Si layer 2, there can be used a sheet type member containing Si as its main component, or an object formed by cutting a Si substrate into a predetermined shape. Alternatively, as Si layer 2, there may be used a Si film formed on the end surfaces of SiC single-crystal ingots 1 by means of, for example, a CVD method or the like.

Further, SiC single-crystal ingots 1 arranged as shown in FIG. 2 preferably have almost the same crystal orientation. For example, in the collected body shown in FIG. 2, each of SiC single-crystal ingots 1 may have a main surface (upper main surface) corresponding to a C plane, a Si plane, or any other crystal plane. Although the plurality of SiC single-crystal ingots 1 preferably have the same crystal orientation as described above, an error or the like introduced in a step of processing makes it difficult for them to have completely the same crystal orientation. Hence, the plurality of SiC single-crystal ingots 1 preferably have the following crystal orientations. For example, one SiC single-crystal ingot 1 having a predetermined crystal orientation is regarded as a reference. The other SiC single-crystal ingots 1 have corresponding crystal orientations each having an angle of deviation (intersecting angle) of not more than 5°, more preferably, not more than 1°.

Next, as shown in FIG. 1, a step (S30) is performed by performing heat treatment in an atmosphere containing carbon. Specifically, the collected body is heated with a gas containing carbon being used as the atmosphere. For example, the heat treatment may be performed under conditions that: a hydrocarbon gas such as acetylene or propane is employed as the atmospheric gas; the atmosphere pressure is set at not less than 1 Pa and not more than an atmospheric pressure; the heating temperature is set at not less than 1400° C. and not more than 1900° C.; and the heating retention time is set at not less than 10 minutes and not more than 6 hours.

As a result, carbon supplied from the atmosphere and silicon in Si layer 2 react with each other to form SiC layers 3 at the upper end and lower end of Si layer 2 (see FIG. 3) as shown in FIG. 4. Here, FIG. 4 is a schematic cross sectional view illustrating a state of the collected body, which is the object subjected to the process in the step (S30) of FIG. 1. It should be noted that FIG. 4 corresponds to FIG. 3.

As shown in FIG. 4, adjacent SiC single-crystal ingots 1 are connected to each other by SiC layers 3. SiC layers 3 may be formed through liquid phase epitaxy of SiC caused by partial melting of Si layer 2. For the formation of SiC layers 3, any heat treatment conditions can be used.

Next, as shown in FIG. 1, a step (S40) is performed to expand the SiC portions. Specifically, by performing heat treatment, Si layer 2 (see FIG. 4) remaining between SiC layers 3 shown in FIG. 4 is converted into a SiC layer 4 as shown in FIG. 5.

In this step (S40), any method can be used to convert Si layer 2 into SiC layer 4. An exemplary method is to form a temperature gradient along a region between SiC single-crystal ingots 1 (region where SiC layer 4 is to be formed) (in the upward/downward direction in FIG. 5 or in the thickness direction of the collected body), so as to grow a SiC layer from the SiC layer 3 sides to the Si layer 2 side using a so-called close-spaced sublimation method. An alternative method is to form a temperature distribution along the upward/downward direction of the region in FIG. 5 so as to grow SiC from the SiC layer 3 sides by means of solution growth. Further, in this step (S40), the heat treatment may be performed under conditions that: acetylene, propane, or the like is used as a silicon carbide gas, i.e., the atmospheric gas; the atmosphere pressure is set at not less than 1 Pa and not more than atmospheric pressure; the heating temperature is set at not less than 1400° C. and not more than 1900° C.; and the heating retention time is set at not less than 10 minutes and not more than 6 hours.

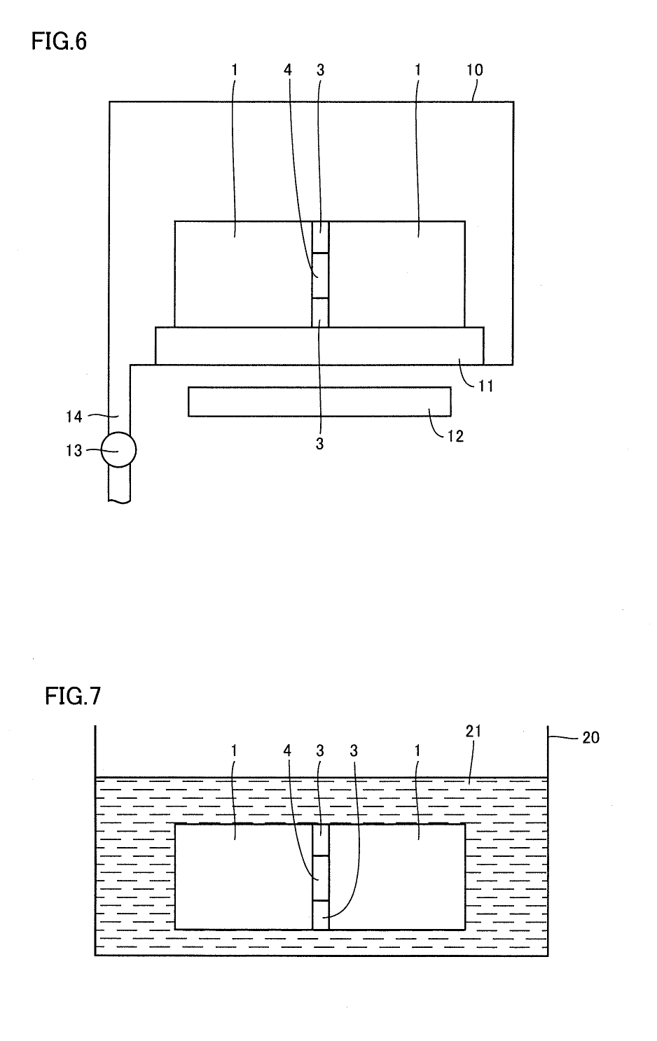

Next, as shown in FIG. 1, a post-process step (S50) is performed. Specifically, from the region converted from Si layer 2 (see FIG. 2) into SiC layers 3, 4 as described above (hereinafter, also referred to as “connecting layer”), remaining silicon (Si) is removed, whereby the connecting layer contains SiC as its main component. In this step (S50), as shown in for example FIG. 6, the collected body constituted by SiC single-crystal ingots 1 and the connecting layer is placed on a susceptor 11 in a heat treatment furnace 10, and is heated by a heater 12 through susceptor 11 with the atmosphere being under reduced pressure in heat treatment furnace 10. It should be noted that the pressure in the heat treatment furnace 10 can be adjusted by discharging the atmospheric gas therein using a vacuum pump 13 via a pipe 14 connected to heat treatment furnace 10. As a result, silicon is sublimated from the connecting layer, whereby the connecting layer can contain SiC as its main component.

It should be noted that in this post-process step (S50), as shown in FIG. 7, the collected body (also referred to as “connected ingot”) constituted by SiC single-crystal ingots 1 and the connecting layer may be soaked in a hydrofluoric-nitric acid solution 21 to remove silicon from the connecting layer. Here, FIG. 6 is a schematic view for illustrating an exemplary process in the post-process step (S50). FIG. 7 is a schematic view for illustrating another exemplary process in the post-process step (S50).

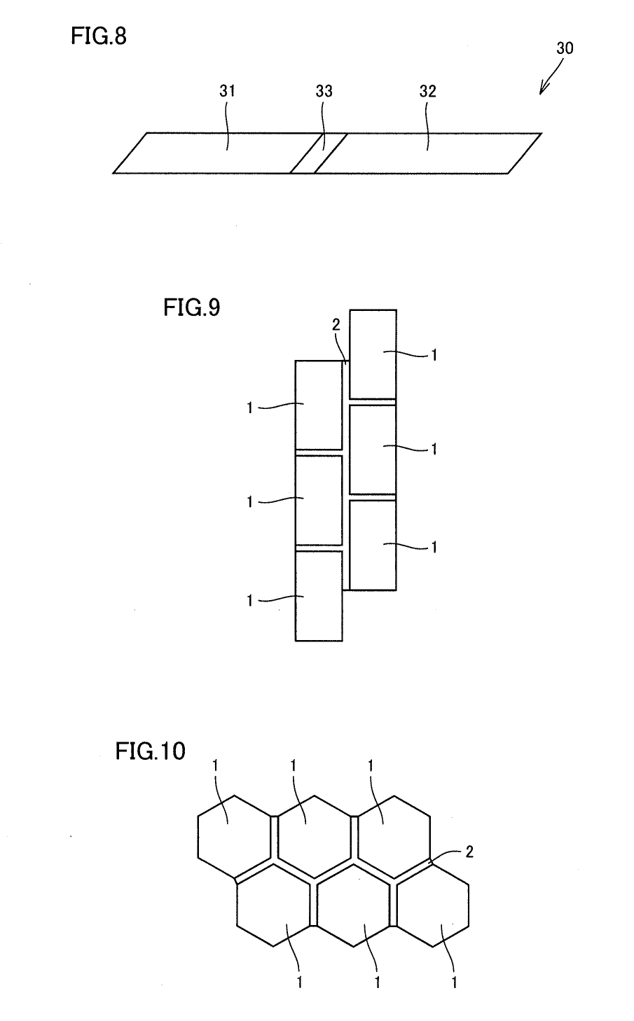

Next, as shown in FIG. 1, a slicing step (S60) is performed. Specifically, the collected body (connected ingot) obtained by connecting the plurality of SiC single-crystal ingots 1 using the connecting layer through steps (S10)-(S50) is cut to obtain a SiC-combined substrate 30 (see FIG. 8) having a main surface exhibiting an appropriate plane orientation. As a result, as shown in FIG. 8, SiC-combined substrate 30 thus obtained has a first region 31 and a second region 32, both of which are connected to each other by a combining region 33. A device usable for this step (S60) is any conventionally known cutting device employing a wire saw or a blade (such as an inner peripheral cutting edge blade or an outer peripheral cutting edge blade). In this way, SiC-combined substrate 30 according to the present invention can be obtained.

Here, combining region 33 shown in FIG. 8 corresponds to SiC layers 3, 4 shown in FIG. 6. Further, first region 31 and second region 32 are parts of SiC single-crystal ingots 1 shown in FIG. 6. Further, first region 31 and second region 32 have predetermined crystal orientations (for example, the <0001> direction) similar to some extent but not completely parallel. Such a difference in crystal orientation can be detected by means of, for example, diffraction orientation measurement on a specific plane by employing X-ray diffraction. For example, the difference in crystal orientation can be checked using a method for detecting a displacement of peak orientations by means of omnidirectional measurement performed using a pole figure method.

Further, first region 31 and second region 32 have crystallinity substantially the same in their thickness directions. Here, the crystallinity can be evaluated from a half width of diffraction angle, which is measured by means of XRD evaluation. Further, the phrase “crystallinity substantially the same in their thickness directions” is specifically intended to mean that variation of the above-described data in the thickness directions is equal to or smaller than a predetermined value (for example, the variation of the data is equal to or smaller than ±10% relative to an average value). Further, based on the method of evaluating the crystallinity as described above, the crystallinity of combining region 33 is inferior to that of each of first region 31 and second region 32.

It should be noted that in step (S20) shown in FIG. 1, as shown in FIG. 2, the plurality of SiC single-crystal ingots 1 are arranged in columns and rows in the form of matrix but they can be arranged in another form. Referring to FIG. 9 and FIG. 10, the following describes variations of the configuration of the collected body having SiC single-crystal ingots 1. Each of FIG. 9 and FIG. 10 is a schematic planar view showing the collected body formed by arranging the plurality of SiC single-crystal ingots 1.

For example, as shown in FIG. 9, in the collected body including the plurality of SiC single-crystal ingots 1, the plurality of SiC single-crystal ingots 1 are arranged in a plurality of columns in step (S20) of FIG. 1 (although two columns are provided in FIG. 9, three or more columns may be provided) in a predetermined direction (upward/downward direction in FIG. 9) with Si layer 2 interposed therebetween. Each of SiC single-crystal ingots 1 is in contact with Si layer 2. The collected body may be configured such that locations of Si layer 2 in the predetermined direction may differ among the columns. In this case, Si layer 2 is configured to extend in three directions at a corner portion of each of SiC single-crystal ingots 1. On the other hand, in the arrangement of SiC single-crystal ingots 1 in the collected body shown in FIG. 2 and FIG. 3, Si layer 2 extends in four directions from the corner portion. Accordingly, the arrangement shown in FIG. 9 provides a smaller volume of Si layer 2 adjacent to the corner portion. This can restrain occurrence of such a problem that SiC layers 3, 4 are not sufficiently formed from Si layer 2 due to a large volume of Si layer 2 at the corner portion in the structure in which SiC single-crystal ingots 1 are to be connected to each other by SiC layers 3, 4 (resulting from Si layer 2) (such a problem that the structure cannot be formed in which adjacent SiC single-crystal ingots 1 are sufficiently connected to each other by SiC layers 3, 4).

Further, an arrangement of the plurality of SiC single-crystal ingots 1 included in the collected body as shown in FIG. 10 may be adopted in step (S20) of FIG. 1. In FIG. 10, each of SiC single-crystal ingots 1 has a hexagonal planar shape. The collected body is configured such that SiC single-crystal ingots 1 each having this hexagonal planar shape (i.e., external shape of hexagonal pillar) have end surfaces facing each other with Si layer 2 interposed therebetween. Also in such a configuration, Si layer 2 extends in three directions at one corner portion of each of SiC single-crystal ingots 1, thereby attaining an effect similar to that in the collected body shown in FIG. 9.

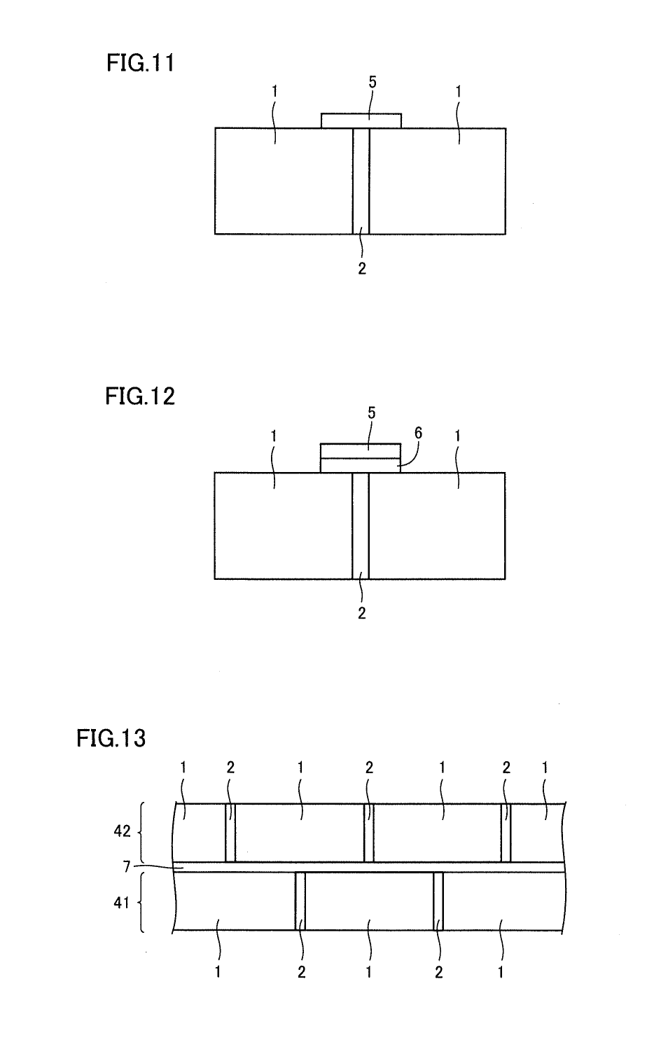

Further, in the above-described method for manufacturing the silicon carbide substrate, in step (S20), a cap member 5 may be provided to cover Si layer 2, which is to serve as the connecting layer, as shown in FIG. 11 or FIG. 12. It should be noted that each of FIG. 11 and FIG. 12 corresponds to FIG. 3. Referring to FIG. 11 and FIG. 12, the following describes variations of the configuration of the collected body including SiC single-crystal ingots 1 in step (S20) of FIG. 1.

As shown in FIG. 11 and FIG. 12, cap member 5 may be provided to cover Si layer 2 in the collected body serving as a workpiece and having Si layer 2 interposed between SiC single-crystal ingots 1. An exemplary, usable cap member 5 is a substrate made of SiC. Cap member 5 basically has any planar shape so far as it is configured to cover the upper end surface of Si layer 2 along the planar shape of Si layer 2. For example, a plurality of substrates (for example, SiC substrates) each having a relatively small size may be arranged along the upper end of Si layer 2. This can restrain Si from being sublimated and dissipated from SiC layers 3, 4 when performing the heat treatment to convert Si layer 2 into SiC layers 3 and the like (when performing step (S30) or step (S40)), for example.

Further, as shown in FIG. 12, a cap Si layer 6 may be disposed under cap member 5. Cap Si layer 6 thus disposed allows for improved adhesion between cap member 5 and each of SiC single-crystal ingots 1. Instead of cap Si layer 6, a layer (cap carbon layer) made of carbon (C) may be disposed.

Further, as shown in FIG. 13, instead of using cap member 5, the following configuration may be employed. That is, a second layer 42 having a plurality of SiC single-crystal ingots 1 arranged is provided to cover the upper surface of a first layer 41 having another set of plurality of SiC single-crystal ingots 1 arranged. First layer 41 and second layer 42 are stacked on each other with an intermediate Si layer 7 interposed therebetween. In each of first layer 41 and second layer 42, each of the end surfaces of adjacent SiC single-crystal ingots 1 is in contact with Si layer 2, which is to become the connecting layer.

On this occasion, it is preferable that the locations of Si layer 2 in contact with the end surfaces of SiC single-crystal ingots 1 in first layer 41 are displaced from those in second layer 42 when viewed in a planar view (they overlap with each other only at a part of the region thereof and most of them do not overlap at the rest of the region). In this way, for first layer 41, second layer 42 can be used as a member that provides an effect similar to that provided by the above-described cap member. Further, with the structure obtained by stacking the two or three layers of SiC single-crystal ingots 1, a larger SiC single-crystal collected body (combined ingot) can be obtained.

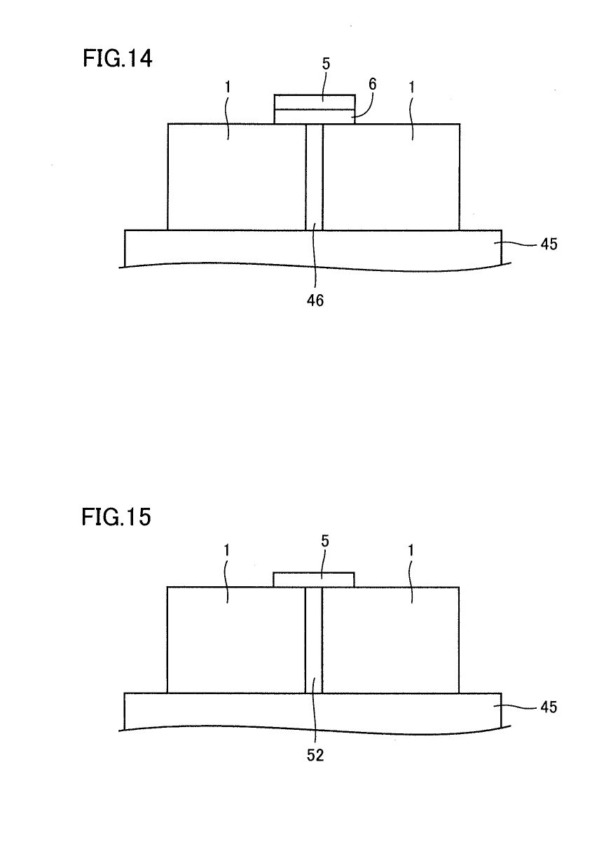

The following describes another variation in step (S20) of FIG. 1, with reference to FIG. 14 and FIG. 15. Each of FIG. 14 and FIG. 15 corresponds to FIG. 3.

As shown in FIG. 14, in step (S20) of FIG. 1, SiC single-crystal ingots 1 are arranged on a base material 45 with a space 46 therebetween. Further, a cap Si layer 6 is disposed to cover space 46. On cap Si layer 6, a cap member 5 made of SiC is disposed. In this state, the entire collected body shown in FIG. 14 is heated to a predetermined temperature, thereby melting cap Si layer 6. This temperature is a temperature at which cap Si layer 6 melts (temperature higher than the melting point of silicon) and is lower than the temperature at which silicon carbide sublimes. In this heat treatment, for example, the heating temperature can be set at not less than 1400° C. and not more than 1900° C., more preferably, not less than 1500° C. and not more than 1800° C. Further, the Si melt formed as a result of melting of cap Si layer 6 flows into space 46 shown in FIG. 14. Thereafter, the temperature is decreased to fall below the melting point of silicon, thereby solidifying the Si melt having flown into space 46.

As a result, as shown in FIG. 15, an inflow Si layer 52 is provided as the solid in the space between SiC single-crystal ingots 1. Further, cap member 5 described above covers the upper end surface of inflow Si layer 52. In this way, there can be obtained the collected body in which SiC single-crystal ingots 1 are combined to each other as shown in FIG. 2 and FIG. 3. Such an inflow Si layer 52 can be also converted into SiC layers by performing step (S30) to step (S50) shown in FIG. 1. As a result, the single-crystal ingot collected body (combined ingot) can be obtained in which SiC single-crystal ingots 1 are connected to each other by the connecting layer (combining layer) constituted by the SiC layers. Then, step (S60) of FIG. 1 is performed, thereby obtaining the SiC-combined substrate. It should be noted that the respective configurations of the above-described embodiments can be combined appropriately.

The following describes characteristic configurations of the present invention, although some of them have been already described above.

The method for manufacturing the silicon carbide substrate according to the present invention is a method for manufacturing a SiC-combined substrate. The method includes: the step (S10) of preparing a plurality of single-crystal bodies each made of silicon carbide (SiC); the step (step (S20) in FIG. 1) of forming a collected body; the step (step (S30) in FIG. 1) of connecting the single-crystal bodies to each other; and the step (step (S60) in FIG. 1) of slicing the collected body. In the step (S20) of forming the collected body, the collected body including the single-crystal bodies is formed by arranging the plurality of single-crystal bodies (SiC single-crystal ingots 1) with a silicon (Si) containing connecting layer (Si layer 2, intermediate Si layer 7, or inflow Si layer 52) interposed therebetween. In the step (S30) of connecting the SiC single-crystal ingots 1 to each other, SiC single-crystal ingots 1 are connected to each other by the connecting layer (Si layer 2, intermediate Si layer 7, or inflow Si layer 52) via at least a portion of the connecting layer, the at least portion being formed into silicon carbide by heating the collected body. In the slicing step (S60) of slicing the collected body, the collected body in which SiC single-crystal ingots 1 are connected to each other is sliced.

Thus, the plurality of SiC single-crystal ingots 1 are connected to each other by SiC layers 3, 4, each of which serves as the connecting layer formed into silicon carbide, so as to form a large ingot (combined ingot) of silicon carbide. Then, this ingot is sliced. In this way, there can be efficiently obtained a plurality of silicon carbide substrates (SiC-combined substrates 30) each having a size larger than that of a silicon carbide substrate obtained by slicing one single-crystal body. When such a SiC-combined substrate 30 having a large size is employed to manufacture semiconductor devices, a greater number of semiconductor devices (chips) can be formed from one SiC-combined substrate 30, as compared with the number in the conventional one. As a result, the manufacturing cost of the semiconductor devices can be reduced.

Further, the large ingot formed as described above is sliced to obtain silicon carbide substrates (SiC-combined substrates 30) of the present invention. Hence, a plurality of SiC-combined substrates can be manufactured at one time as compared with a case of forming SiC-combined substrates (silicon carbide substrate) one by one by connecting single-crystal bodies having a relatively thin thickness to each other. Accordingly, the manufacturing cost of SiC-combined substrates 30 can be reduced as compared with the case of forming silicon carbide substrates (SiC-combined substrates) one by one by connecting single-crystal bodies each having a thin thickness.

The method for manufacturing the silicon carbide substrate may further include the step (step (S50) in FIG. 1) of removing silicon from the connecting layer after the step of connecting (step (S30) in FIG. 1) and before the step of slicing (step (S60) in FIG. 1).

In this case, no silicon (Si) remains in SiC layers 3, 4 each serving as the connecting layer. This restrains occurrence of a problem resulting from silicon remaining in SiC layers 3, 4 (combining region 33 in SiC-combined substrate 30). For example, if silicon remains in combining region 33 serving as the connecting layer of the silicon carbide substrate (SiC-combined substrate 30), silicon may be released to outside from combining region 33 when a temperature in heat treatment for SiC-combined substrate 30 or the like is around the melting point of silicon. When silicon is thus released from combining region 33 to outside, density of combining region 33 is decreased to highly likely result in decreased hardness in combining region 33. The decreased hardness in combining region 33 may result in damage of SiC-combined substrate 30 or may result in the released silicon providing an adverse effect over the process on SiC-combined substrate 30. However, by performing the above-described step (S50), occurrence of the above-described problems can be restrained.

In the step of connecting (step (S30) in FIG. 1) in the method for manufacturing the silicon carbide substrate, a liquid phase epitaxy method (LPE method) may be employed to form the at least portion of the connecting layer (Si layer 2, intermediate Si layer 7, or inflow Si layer 52) into silicon carbide. In this case, the portion of Si layer 2 can be securely formed into silicon carbide.

In the step of connecting (step (S30) in FIG. 1) in the method for manufacturing the silicon carbide substrate, the portion of the connecting layer (Si layer 2 and intermediate Si layer 7) is formed into silicon carbide. Further, the method for manufacturing the silicon carbide substrate may further include the step (step (S40) in FIG. 1) of growing silicon carbide from the portion (SiC layers 3) formed into silicon carbide in the connecting layer to a portion (for example, Si layer 2 of FIG. 4) not formed into silicon carbide in the connecting layer by heating, after step (S30) of FIG. 1, i.e., after the step of connecting, the collected body to form a temperature gradient in the direction in which the connecting layer extends (for example, in the thickness direction thereof, which is the direction in which Si layer 2 extends). Further, in the step of connecting (step (S30) in FIG. 1), the collected body may be heated in an atmosphere containing carbon.

In this case, a ratio of silicon carbide in the connecting layer formed into silicon carbide can be increased. Accordingly, SiC single-crystal ingots 1 can be connected to each other with improved strength provided by the connecting layer thus formed into silicon carbide (SiC layers 3, 4 of FIG. 6, also referred to as connection layer).

In the step (step (S20) in FIG. 1) of forming the collected body in the method for manufacturing the silicon carbide substrate, a sheet type member containing silicon as its main component may be used as the connecting layer (Si layer 2 or intermediate Si layer 7). In this case, the sheet type member is disposed between SiC single-crystal ingots 1, thereby readily constituting the collected body.

In the method for manufacturing the silicon carbide substrate, the step (step (S20) in FIG. 1) of forming the collected body may include: the step of arranging the plurality of SiC single-crystal ingots 1 with a space therebetween as shown in FIG. 14; the step of disposing a connecting member (cap Si layer 6 of FIG. 14) to cover the space, the connecting member containing silicon as its main component; and the step of forming the connecting layer (inflow Si layer 52) by heating and melting the connecting member (cap Si layer 6) and letting the melted connecting member flow into the space.

In this case, the melted connecting member flows into the space, thereby entirely filling the space with melted cap Si layer 6. The space thus filled with inflow Si layer 52 allows the connecting member (i.e., inflow Si layer 52) to securely make contact with the end surfaces (surfaces at the space) of SiC single-crystal ingots 1. Accordingly, a portion obtained by forming inflow Si layer 52 into silicon carbide can make contact with SiC single-crystal ingots 1 more securely.

In the step (step (S20) in FIG. 1) of forming the collected body in the method for manufacturing the silicon carbide substrate, a chemical vapor deposition method (CVD method) may be employed to form the connecting layer (Si layer 2 or intermediate Si layer 7). In this case, unlike the step of preparing the sheet type connecting layers and disposing them between SiC single-crystal ingots 1 individually, Si layer 2 can be formed all at once using the CVD method in the predetermined space which is interposed between the plurality of SiC single-crystal ingots 1. Accordingly, the step (step (S20) in FIG. 1) of forming the collected body can be simplified, which results in reduced manufacturing cost of SiC-combined substrate 30.

In the step (step (S30) in FIG. 1) of connecting in the method for manufacturing the silicon carbide substrate, the collected body may be heated with a cover member (cap member 5) provided to cover the end surface of the connecting layer (Si layer 2, intermediate Si layer 7, or inflow Si layer 52). In this case, when the portion of the connecting layer (Si layer 2) is formed into silicon carbide in step (S30) in FIG. 1, silicon is restrained from being released from Si layer 2, and Si layer 2, i.e., the connecting layer is restrained from being temporarily melted and leaked from the region in which Si layer 2 is disposed (space between SiC single-crystal ingots 1).

In the method for manufacturing the silicon carbide substrate, the cover member (cap member 5) may contain one of silicon carbide (SiC) and carbon (C) as its main component. In this case, cap member 5 is constituted by a material having a sufficiently high melting point. Hence, cap member 5 can be prevented from being damaged by the heat treatment performed in step (S30).

In the step (step (S30) in FIG. 1) of connecting in the method for manufacturing the silicon carbide substrate, an intermediate layer (cap Si layer 6) may be disposed between cap member 5 and the collected body. In this case, unlike the material of cap member 5, a material excellent in adhesion with the collected body (SiC single-crystal ingots 1 and Si layer 2 serving as the connecting layer) can be selected as the material of the intermediate layer. Accordingly, the end surface of Si layer 2 serving as the connecting layer can be securely covered with cap member 5 and cap Si layer 6.

In the method for manufacturing the silicon carbide substrate, the intermediate layer (cap Si layer 6) may contain one of silicon (Si) and carbon (C) as its main component. Particularly, in the case where silicon is used for the intermediate layer, adhesion between the intermediate layer and the collected body can be improved more.

A SiC-combined substrate 30, which is a silicon carbide substrate according to the present invention, includes: a plurality of single-crystal regions (first region 31 and second region 32 in FIG. 8) each made of silicon carbide; and a connecting layer (combining region 33). Combining region 33 is made of silicon carbide (SiC), is located between the plurality of single-crystal regions (first region 31 and second region 32), and connects the single-crystal regions (first region 31 and second region 32) to each other. The single-crystal regions (first region 31 and second region 32) are formed to extend from the first main surface of SiC-combined substrate 30 (upper main surface in FIG. 8) to the second main surface thereof opposite to the first main surface (the underlying backside surface of SiC-combined substrate 30). Crystallinity in the single-crystal regions (first region 31 and second region 32) are substantially the same in the direction of thickness from the first main surface to the second main surface. The plurality of single-crystal regions (first region 31 and second region 32) are different from each other in terms of crystal orientation in the first main surface. Combining region 33 has crystallinity inferior to that of each of the single-crystal regions (first region 31 and second region 32).

With the configuration described above, the plurality of single-crystal regions (first region 31 and second region 32) are connected by combining region 33. Accordingly, there can be realized a silicon carbide substrate (SiC-combined substrate 30) having a main surface having a larger area than that of a silicon carbide substrate constituted by one single-crystal region. Accordingly, a larger number of semiconductor devices can be obtained from one silicon carbide substrate during formation of semiconductor devices. This leads to reduced manufacturing cost of the semiconductor devices.

Further, the single-crystal regions (first region 31 and second region 32) have substantially the same crystallinity in the direction of thickness from the first main surface to the second main surface. Hence, when forming a vertical type device, no problem takes place due to locally inferior crystallinity in the thickness direction of SiC-combined substrate 30.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

The present invention is particularly advantageously applied to a substrate having a structure obtained by combining a plurality of single-crystal bodies each made of silicon carbide.

### REFERENCE SIGNS LIST

1: SiC single-crystal ingot; 2: Si layer; 3, 4: SiC layer; 5: cap member; 6: cap Si layer; 7: intermediate Si layer; 10: heat treatment furnace; 11: susceptor; 12: heater; 13: vacuum pump; 14: pipe; 21: hydrofluoric-nitric acid solution; 30: SiC-combined substrate; 31: first region; 32: second region; 33: combining region; 41: first layer; 42: second layer; 45: base material; 46: space; 52: inflow Si layer.

1. A method for manufacturing a silicon carbide substrate comprising the steps of:
preparing a plurality of single-crystal bodies each made of silicon carbide;
forming a collected body including said single-crystal bodies by arranging said plurality of single-crystal bodies with a connecting layer interposed therebetween, said connecting layer containing silicon;
connecting adjacent single-crystal bodies to each other by said connecting layer via at least a portion of said connecting layer, said at least portion being formed into silicon carbide by heating said collected body; and
slicing said collected body in which said single-crystal bodies are connected to each other.

2. The method for manufacturing the silicon carbide substrate according to claim 1, wherein in the step of connecting, a liquid phase epitaxy method is used to form said at least portion of said connecting layer into silicon carbide.

3. The method for manufacturing the silicon carbide substrate according to claim 1, wherein:
in the step of connecting, the portion of said connecting layer is formed into silicon carbide,
the method further comprising the step of growing silicon carbide from the portion formed into silicon carbide in said connecting layer to a portion not formed into silicon carbide in said connecting layer by heating, after the step of connecting, said collected body to form a temperature gradient in a direction in which said connecting layer extends.

4. The method for manufacturing the silicon carbide substrate according to claim 1, wherein in the step of connecting, said collected body is heated in an atmosphere containing carbon.

5. The method for manufacturing the silicon carbide substrate according to claim 1, wherein in the step of forming said collected body, a sheet type member containing silicon as its main component is used as said connecting layer.

6. The method for manufacturing the silicon carbide substrate according to claim 1, wherein:
the step of forming said collected body includes the steps of
arranging said plurality of single-crystal bodies with a space therebetween,
disposing a connecting member containing silicon as its main component so as to cover said space, and
forming said connecting layer by heating and melting said connecting member and letting said connecting member thus melted flow into said space.

7. The method for manufacturing the silicon carbide substrate according to claim 1, wherein in the step of forming said collected body, a chemical vapor deposition method is used to form said connecting layer.

8. The method for manufacturing the silicon carbide substrate according to claim 1, wherein in the step of connecting, said collected body is heated with a cover member disposed to cover an end surface of said connecting layer.

9. The method for manufacturing the silicon carbide substrate according to claim 8, wherein said cover member contains one of silicon and carbon as its main component.

10. The method for manufacturing the silicon carbide substrate according to claim 8, wherein in the step of connecting, an intermediate layer is disposed between said cover member and said collected body.

11. The method for manufacturing the silicon carbide substrate according to claim 10, wherein said intermediate layer contains one of silicon carbide and carbon as its main component.

12. A silicon carbide substrate comprising:
a plurality of single-crystal regions each made of silicon carbide; and
a connection layer made of silicon carbide, located between said plurality of single-crystal regions, and connecting said single-crystal regions to each other,
each of said single-crystal regions being formed to extend from a first main surface of said silicon carbide substrate to a second main surface thereof opposite to said first main surface,
said single-crystal regions having the same crystallinity in a direction of thickness from said first main surface to said second main surface,
said plurality of single-crystal regions being different from each other in terms of crystal orientation in said first main surface,
said connection layer having crystallinity inferior to that of each of said single-crystal regions.
